(19) United States
(12) Patent Application Publication
(10) Pub. No.: US 2026/0189136 A1
(43) Pub. Date: Jul. 2, 2026

(54) CONTROLLER AND CONTROL METHOD FOR CONVERTER INCLUDING MULTIPLE PFC CIRCUITS

(71) Applicant: HYUNDAI AUTOEVER CORP., Seoul (KR)

(72) Inventors: Woo Won Rhee, Seoul (KR); Eun Su Jun, Seoul (KR)

(73) Assignee: HYUNDAI AUTOEVER CORP., Seoul (KR)

(21) Appl. No.: 19/435,452

(22) Filed: Dec. 29, 2025

(30) Foreign Application Priority Data
Dec. 30, 2024 (KR) 10-2024-0200633

(51) Int. Cl. H02M 1/42; B60L 53/20; H02M 3/04; H02M 7/23; H03K 7/08

(52) U.S. Cl. CPC H02M 1/4216; H02M 3/04; H02M 7/23; H03K 7/08; B60L 53/20

(57) ABSTRACT

A converter controller includes a core configured to calculate Pulse Width Modulation (PWM) control values for first switches included in a first Power Factor Correction (PFC) circuit and store the PWM control values in a first new-data variable in each control period. A value of a first state variable is changed before and after storing the PWM control values in the first new-data variable in each control period, and a value of the first new-data variable is stored in a first pre-data variable. The converter controller further includes a second core configured to calculate PWM control values for second switches included in a second PFC circuit; set registers for outputting PWM signals for the second switches in the same control period; select one of the values of the first new-data variable and the first pre-data variable; and set registers for outputting PWM signals for the first switches.

### CROSS REFERENCE TO RELATED APPLICATION

This application claims the benefit of and priority to Korea Patent Application No. 10-2024-0200633, filed on Dec. 30, 2024, the entire contents of which are hereby incorporated herein by reference.

### TECHNICAL FIELD

The present disclosure relates to a technique for controlling a converter including power factor correction (PFC) circuits.

### BACKGROUND

The statements in this section merely provide background information related to the present disclosure and may not constitute prior art.

An electric automobile may have an on-board charger (OBC). An OBC may be a device that converts alternating current supplied by an external power source into direct current that can be used inside an automobile. This device may supply power that has been converted into voltages and currents suitable for a battery pack for an electric automobile. Additionally, an OBC may control currents and voltages in the process of power conversion, thereby preventing a battery from being overcharged or damaged.

An OBC may include power factor correction (PFC) circuits. A PFC circuit may be a circuit designed to maintain a constant power factor of alternating current supplied by an external source. This circuit may operate in a way that matches the phases of input current and input voltage, which contributes to the increase in current flow efficiency and the reduction of power loss. Additionally, the PFC circuit may further have a filtering function to reduce electromagnetic interference in an electrical grid. This circuit may improve the waveforms of input currents of the OBC, thereby enabling a stable power supply during battery charging.

A PFC circuit may be limited in the power capacity that it can handle. The capacity of a switch included in a PFC circuit may be one of the elements that determine the maximum power that the circuit can handle. The capacity of a switch may be determined by the limits of current and voltage and, when a switch operates in excess of a designed reference, it may undergo overheating or damage. In addition, the capacity of an input filter included in a PFC circuit may also affect the power capacity. The input filter is intended to reduce electromagnetic interference of power that flows in the circuit. When the capacity of the filter is limited, the performance of the filter may decrease under a high power condition. The capacity of a power line may also affect the limit of power that the circuit can handle. When the power line is overloaded, it may hinder a stable power transmission. Such elements may vary depending on the design and configuration of a PFC circuit.

In order to increase the power capacity of PFC circuits, multiple PFC circuits may be arranged in parallel inside an OBC. Each of the PFC circuits arranged in parallel may independently handle power, and a system of the entire PFC circuits may support a higher power capacity in comparison with a single PFC circuit. Such an arrangement allows reducing that power load that each PFC circuit handles so as to lower the possibility of overheating or overload of individual circuits. Additionally, in a parallel arrangement, even when a certain circuit is in fault, the remaining circuits still can operate so that the stability of the entire system may be maintained.

In order to operate multiple PFC circuits in parallel, the control periods, switching periods, or duties of two PFC circuits need to be synchronized. Synchronizing control periods may mean that the control signals of two PFC circuits are adjusted to operate at the same interval. Synchronizing duties may mean that the two PFC circuits are controlled to maintain the same duty cycle. Such synchronization may be a method for minimizing the imbalance of currents and voltages of the circuits connected in parallel. Without synchronization, there may be cases in which certain circuits handle excessive power and undergo overheating or performance deterioration.

### SUMMARY

An aspect of the present disclosure provides a technique for controlling multiple PFC circuits by synchronizing them. Another aspect of the present disclosure provides a technique for ensuring coherence of data when multiple PFC circuits are controlled by different cores.

According to an embodiment, a converter controller is provided. The converter controller includes a first core configured to calculate pulse width modulation (PWM) control values for first switches included in first power factor correction (PFC) circuit and store the PWM control values in a first new-data variable in each control period. A value of a first state variable is changed before and after storing the PWM control values in the first new-data variable in each control period. A value of the first new-data variable is stored in a first pre-data variable after storing the PWM control values in the first new-data variable in each control period. The converter controller further includes a second core configured to calculate PWM control values for second switches included in a second PFC circuit; set registers for outputting PWM signals for the second switches in the same control period; select one of the values of the first new-data variable and the first pre-data variable; and set registers for outputting PWM signals for the first switches.

The first core may set the first state variable to a first value before storing the PWM control values for the first switches in the first new-data variable and may set the first state variable to a second value after storing the PWM control values for the first switches in the first new-data variable.

The second core may set the registers for outputting PWM signals for the first switches based on the first new-data variable when the first state variable includes the second value and may set the registers for outputting PWM signals for the first switches based on the first pre-data variable when the first state variable includes the first value.

The second core may calculate the PWM control values for the second switches and store the PWM control values for the second switches in a second new-data variable. A value of second state variable is stored before and after storing the PWM control values for the second switches in the second new-data variable. A value of the second new-data variable is stored in a second pre-data variable after storing the PWM control values for the second switches in the second new-data variable.

The second core may set registers for outputting PWM signals for the second switches by selecting one of the values of the second new-data variable and the second pre-data variable based on the value of the second state variable.

The second core may, in a top-level Interrupt Service Routine (ISR), set registers for outputting PWM signals for the first switches and registers for outputting PWM signals for the second switches.

The top-level ISR may be invoked at a predetermined time before a start time of a new control period and may be terminated before the start time of the new control period.

The PWM control values may include at least one of a value indicating a duty of a PWM signal or a value indicating a period of the PWM signal.

The second core may generate a rising-edge time value or a falling-edge time value of a PWM signal from one of a value of the first new-data variable and a value of the first pre-data variable and may store the rising-edge time value or the falling-edge time value in the registers for outputting PWM signals for the first switches.

The converter controller may include Timer Output Modules (TOMs) configured to output PWM signals respectively to the first switches and the second switches. The second core may set shadow registers (SRs) corresponding to the respective TOMs.

Each TOM may include a first CM register used for setting a rising edge of a PWM signal and a second CM register used for setting a falling edge of the PWM signal. Values stored in a shadow register may be transferred, at a start of a control period, to the first CM register and the second CM register.

In each control period, the first core may calculate PWM control values for the first switches after performing acquiring Analog-Digital-Converter (ADC) sensing values, performing a voltage control process, and performing a current control process for the first PFC circuit. Similarly, the second core may calculate PWM control values for the second switches after acquiring ADC sensing values, performing a voltage control process, and performing a current control process for the second PFC circuit.

The first core may increase a value of a count variable before storing the value of the first new-data variable in the first pre-data variable. When the value of the count variable has not been increased, the second core may set registers for outputting PWM signals for the first switches according to a value of the pre-data variable.

The first new-data variable and the first pre-data variable may be located in a buffer shared by the first core and the second core.

According to another embodiment, a converter control method is provided. The converter control method includes calculating, by a first core, Pulse Width Modulation (PWM) control values for first switches included in a first Power Factor Correction (PFC) circuit. The converter control method further includes calculating, by a second core, PWM control values for second switches included in a second PFC circuit. The converter control method further includes storing, by the first core, the PWM control values of the first switches in a first new-data variable. The converter control method further includes storing, by the second core, the PWM control values of the second switches in a second new-data variable. A value of a first state variable is changed before and after storing the PWM control values of the second switches in the second new-data variable. A value of the second new-data variable is stored in a second pre-data variable after storing the PWM control values of the second switches in the second new-data variable. The converter control method further includes setting, by the first core, registers for outputting PWM signals for the first switches based on the PWM control values of the first switches. The converter control method further includes selecting, by the first core based on the value of the first state variable, one of values of the second new-data variable and the second pre-data variable to set registers for outputting PWM signals for the second switches.

Storing the PWM control values of the second switches in the second new-data variable may include setting, by the second core, the value of the first state variable to a first value before storing the PWM control values of the second switches in the second new-data variable and may include setting, by the second core, the value of the first state variable to a second value after storing the PWM control values of the second switches in the second new-data variable.

Setting the registers for outputting PWM signals for the second switches may include setting, by the first core, registers for outputting PWM signals for the second switches based on a value of the second new-data variable when the value of the state variable is the second value and may may include setting, by the first core, registers for outputting PWM signals for the second switches based on a value of the second pre-data variable when the value of the first state variable is the first value.

Storing the PWM control values of the first switches in the first new-data variable may include calculating, by the first core, the PWM control values of the first switches and may include storing, by the first core, the PWM control values of the first switches in the first new-data variable. A value of another state variable is changed before and after storing the PWM control values of the first switches in the first new-data variable. A value of the first new-data variable is stored in a first pre-data variable after storing the PWM control values of the first switches in the first new-data variable. Setting the registers for outputting PWM signals for the first switches may include setting, by the first core, registers for outputting PWM signals for the first switches based on a value of the first new-data variable when the value of the second state variable is a second value and may include setting, by the first core, registers for outputting PWM signals for the first switches based on a value of the first pre-data variable when the value of the second state variable a the first value.

Setting the registers for outputting PWM signals for the first switches may be performed in a top-level Interrupt Service Routine (ISR) of the first core.

The top-level ISR may be invoked at a predetermined time before a start time of a new control period and may be terminated before the start time of the new control period.

As described above, according to the present disclosure, a plurality of PFC circuits may be controlled in a synchronized manner. Further, according to the present disclosure, when the plurality of PFC circuits is controlled by different cores, data consistency may be ensured.

### BRIEF DESCRIPTION OF THE DRAWINGS

In order for one having ordinary skill in the art to understand the present disclosure, various forms of the present disclosure are described given by way of example with reference to the accompanying drawings, in which:

FIG. 1 is a schematic diagram of a converter according to an embodiment of the present disclosure;

FIG. 2 is a schematic diagram of a power factor correction (PFC) power stage according to an embodiment of the present disclosure;

FIG. 3 is a waveform diagram of a first pulse width modulation (PWM) a-phase signal and a second PWM a-phase signal according to an embodiment of the present disclosure;

FIG. 4 is a schematic diagram showing elements that determine control values of each PWM signal according to an embodiment of the present disclosure;

FIG. 5 is a diagram showing a control process that one core performs in one control period;

FIG. 6 is a schematic diagram illustrating problems that may occur when one core simultaneously controls two PFC circuits during one control period;

FIG. 7 is a schematic diagram showing that two cores respectively control two PFC circuits in a converter controller according to an embodiment of the present disclosure;

FIG. 8 is a schematic diagram of a converter controller according to an embodiment of the present disclosure;

FIG. 9 is a schematic diagram of a timer output module (TOM) channel according to an embodiment of the present disclosure;

FIG. 10 is a schematic diagram showing a process execution procedure of the cores and waveforms of main signals according to an embodiment of the present disclosure;

FIG. 11 is a flowchart illustrating a control method of a converter according to an embodiment of the present disclosure;

FIG. 12 is a detailed flowchart of step S1104 in the flow diagram of FIG. 11;

FIG. 13 is a detailed flowchart of step S1106 in the flow diagram of FIG. 11; and

FIG. 14 is a detailed flowchart of step S1108 in the flow diagram of FIG. 11.

### DETAILED DESCRIPTION

Hereinafter, embodiments of the present disclosure are described in detail with reference to illustrative drawings. When the reference numerals are assigned to components in each drawing, it should be noted that the same reference numerals are assigned to the same or equivalent components as possible, even when the same or equivalent components appear in different drawings. In addition, in describing the present disclosure, where it was determined that detailed description of publicly known configurations or functions in the related art may obscure the concept of the present disclosure, the detailed description thereof has been omitted.

In addition, terms, such as first, second, a, and b, may be used to describe the components of embodiments of the present disclosure. These terms are only intended to distinguish one component from another component and do not limit a feature, an order, or a sequence of the components. When it is described that one component is “connected,” “coupled,” or “joined” to another component, one component may be directly connected or joined to another component. However, it should be understood that an intervening component may be “connected,” “coupled,” or “joined” between the components.

When a component, controller, device, element, apparatus, circuit, unit, or the like of the present disclosure is described as having a purpose or performing an operation, function, or the like, the component, controller, device, element, apparatus, circuit, unit or the like should be considered herein as being “configured to” meet that purpose or to perform that operation or function. Each component, controller, device, element, apparatus, circuit, unit, and the like may separately embody or be included with a processor and a memory, such as a non-transitory computer readable media, as part of the apparatus.

Terms, such as “. . . circuit,” “. . . unit,” etc., in the present disclosure may mean a unit that may process at least one function or operation described in the present disclosure, and this may be implemented by hardware, software, or a combination thereof. In addition, according to embodiments described below, at least a partial configuration or function the destination arrival time estimation method and device may be implemented as a program or software, and the program or software may be stored in a computer-readable recording medium or storage medium.

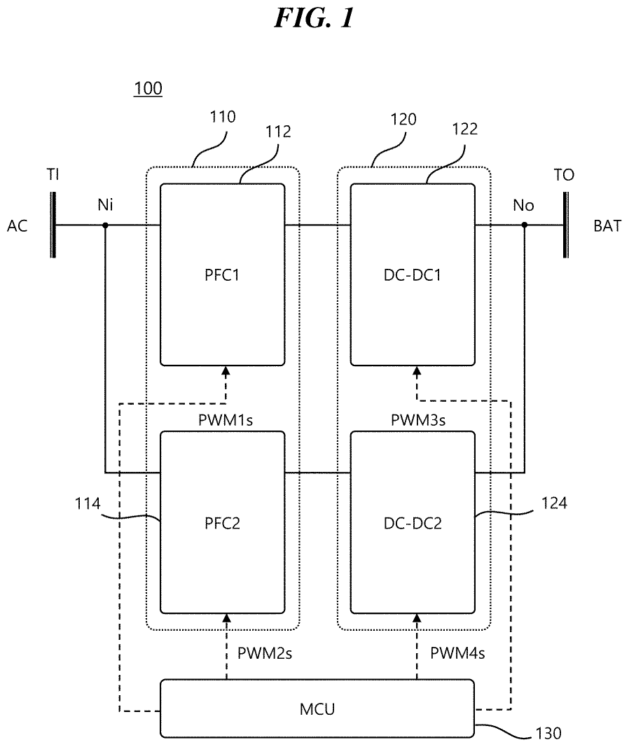

FIG. 1 is a schematic diagram of a converter according to an embodiment of the present disclosure.

Referring to FIG. 1, a converter 100 may comprise a power factor correction (PFC) power stage 110, a DC/DC power stage 120, and a converter controller 130.

The converter 100 may be an on-board charger (OBC). When the converter 100 is an OBC, a load connected to the converter 100 may be a battery BAT.

The converter 100 may be an OBC. The converter 100 may be an electric power converting device and may convert alternating current supplied from an external power source into direct current to supply electric power required for charging a battery. The OBC may monitor the state of charge of the battery, and control charging current and voltage in order to prevent damages due to overcharging or overcurrent. In addition, the OBC may be designed to stably operate under the conditions of various input voltages and include a power factor correction (PFC) function in order to reduce interference with the power grid.

A load connected to the converter 100 may be a battery BAT. The battery BAT may be a main energy storage device of an electric vehicle, and battery cells mainly based on lithium-ion may be used. The battery BAT may store power converted by the converter 100, and the stored energy may be used to operate a motor of an electric vehicle and to supply power to other electronic devices. The battery BAT may be designed to repeat the charging and discharging processes, and a battery management system (BMS) that monitors conditions such as temperatures, voltages, and currents may be used.

In the converter 100, the PFC power stage 110 may be supplied with alternating power and convert it into direct power. The DC/DC power stage 120 may adjust the level of a voltage or current of the direct power supplied from the PFC power stage 110 and may supply the power to the load.

The DC/DC power stage 120 may comprise multiple DC/DC converting circuits 122, 124. The DC/DC converting circuits 122, 124 may be power converting circuits that can convert voltages or currents of the input direct power and generate voltages or currents suitable for a load. These circuits may be designed to enhance power transmission efficiency and may adjust power to be suitable for the conditions required by the load.

The DC/DC converting circuits 122, 124 may be step-down converting circuits that convert an output voltage to be lower than an input voltage. A step-down converting circuit may mainly use a buck converter configuration and may convert an input voltage into a low voltage suitable for a load through a controlled switching operation. Such conversion allows the minimization of power loss and a stable power supply corresponding to an allowable voltage range of a voltage for a load.

The DC/DC converting circuits 122, 124 may be step-up converting circuits that convert an output voltage to be higher than an input voltage. A step-up converting circuit may mainly use a boost converter configuration and may convert a low input voltage into a high output voltage using a switching operation and an energy storage element. These circuits may be designed to be able to supply a voltage required by a load even when an input voltage is low.

The DC/DC converting circuits 122, 124 may be designed to support bi-directional power conversion in addition to the step-down and step-up conversions. In this case, these circuits may include a function of adjusting voltages and currents based on the direction in which power flows.

The PFC power stage 110 may comprise multiple PFC circuits 112, 114, and the DC/DC converting circuits 122, 124 may be connected respectively to the PFC circuits 112, 114 to operate therewith.

The PFC circuits 112, 114 are circuits that may be supplied with alternating power and convert it into direct power. These circuits may convert alternating power (AC) input from an external power source into direct power (DC) usable by an electrical load through rectification and filtering. The PFC circuits 112, 114 may include a function to compensate power factor by adjusting phases of input currents and may input voltages during the process of power conversion.

The PFC circuits 112, 114 may be designed to adjust the waveforms of the input currents so as to maintain the same phase as that of the input voltages. This allows the efficient use of power supplied from a power grid and may contribute to the reduction of power loss and electromagnetic interference. The PFC circuits 112, 114 may choose an active PFC method in order to implement such power factor correction.

In an active PFC method, the PFC circuits 112, 114 may comprise switches. The converter may control the switches to dynamically regulate input currents and may perform precise power factor correction.

In the PFC circuits 112, 114 and the DC/DC converting circuits 122, 124, multiple switches may be arranged. The switches may be, for example, metal-oxide semiconductor field-effect transistors (MOSFETs), insulated gate bipolar transistors (IGBTs), bipolar junction transistors (BJTs), or the like.

A MOSFET may be an element in which a voltage is applied between a gate and a source to control a current between a drain and the source. A MOSFET is a voltage-control type element in which the conducting state of a channel may be adjusted based on a voltage applied to a gate. A drain-source current may be determined based on the gate voltage. It has an excellent switching property, and thus, may be widely used in switching applications.

An IGBT is an element having both the properties of a MOSFET and a BJT, in which a collector-emitter current may be controlled by applying a voltage between a gate and an emitter. An IGBT may handle high voltages and may be configured to have an input property of a MOSFET and an output property of a BJT. Such a feature allows an IGBT to be used in applications requiring a high power density.

A BJT is configured of three terminals, which are a base, a collector, and an emitter, in which a current between a collector and an emitter may be controlled by applying a base current. A BJT is a current-control type element in which a collector current may be amplified by the base current. Such an amplification property allows the BJT to be used in a current amplifier and provides an advantage of handling high currents in certain applications.

The converter controller 130 may perform pulse width modulation (PWM) control over such switches. The converter controller 130 may control the duty of each switch and the switching period or switching frequency for each switch through the PWM control.

A PWM control may be a method of regulating times when a switch is turned on or off to generate a desired output voltage or current. The converter controller 130 may regulate the duty of each switch through such PWM control. The duty, which indicates a ratio of a time during which a switch is turned on, may be used to control the magnitude of output power.

The converter controller 130 may control the switching period or switching frequency for each switch in addition to the duty. The switching period may indicate a time during which a switch is turned on, and then, off once, and the switching frequency may indicate the number of times that switching operations repeat for one second. The control over the switching period or switching frequency may affect the quality of output power and the efficiency of power conversion and may be related to the heat management of a power element.

The converter controller 130 may comprise a circuit or algorithm to monitor input signals regarding voltages, currents, temperatures, and the like in order to adjust the state of a switch in real time, and to generate a PWM signal based on them.

To an input terminal TI of the converter 100, alternating power AC may be supplied, and to an output terminal TO of the converter 100, a load, for example a battery BAT, may be connected. An input node Ni may be formed at the input terminal TI, and an output node No may be formed at the output terminal TO.

A first PFC circuit 112 and a second PFC circuit 114 may share the input node Ni, and a first DC/DC converting circuit 122 and a second DC/DC converting circuit 124 may share the output node No. The first PFC circuit 112 may convert alternating power formed at the input node Ni into direct power to supply it to the first DC/DC converting circuit 122, and the first DC/DC converting circuit 122 may convert a voltage or current of the direct power to supply it to the output node No. The second PFC circuit 114 may convert alternating power formed at the input node Ni into direct power to supply it to the second DC/DC converting circuit 124, and the second DC/DC converting circuit 124 may convert a voltage or current of the direct power to supply it to the output node No.

For such power conversion of each circuit 112, 114, 122, 124, the converter controller 130 may output a first PWM signal PWM1s to the first PFC circuit 112 and a second PWM signal PWM2s to the second PFC circuit 114. Additionally, the converter controller 130 may output a third PWM signal PWM3s to the first DC/DC converting circuit 122 and a fourth PWM signal PWM4s to the second DC/DC converting circuit 124.

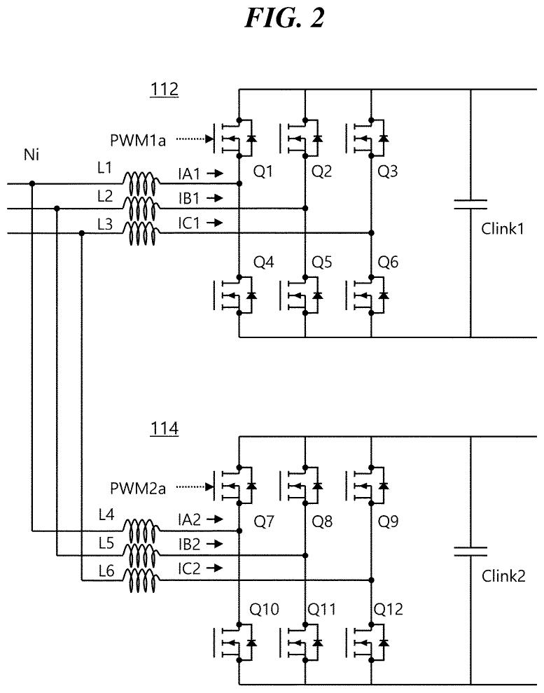

FIG. 2 is a schematic diagram of a PFC power stage according to an embodiment of the present disclosure.

Referring to FIG. 2, the PFC power stage may comprise the first PFC circuit 112 and the second PFC circuit 114. The first PFC circuit 112 and the second PFC circuit 114 may share the input node Ni.

Power supplied to the input node Ni may be three-phase power. Depending on embodiments, the power supplied to the input node Ni may be a single-phase power. However, for the convenience of the description, a case in which three-phase power is supplied to the input node Ni will be described.

In each of the PFC circuits 112, 114, input filters may be disposed. A first inductor L1 may be disposed for phase A of the first PFC circuit 112, a second inductor L2 may be disposed for phase B thereof, and a third inductor L3 may be disposed for phase C thereof. A fourth inductor L4 may be disposed for phase A of the second PFC circuit 114, a fifth inductor L5 may be disposed for phase B thereof, and a sixth inductor L6 may be disposed for phase C thereof.

In each of the PFC circuits 112, 114, a pair of switches may be connected to each phase. In the first PFC circuit 112, a first switch Q1 and a fourth switch Q4 may be disposed for phase A, a second switch Q2 and a fifth switch Q5 may be disposed for phase B, and a third switch Q3 and a sixth switch Q6 may be disposed for phase C. In the second PFC circuit 114, a seventh switch Q7 and a tenth switch Q10 may be disposed for phase A, an eighth switch Q8 and an eleventh switch Q11 may be disposed for phase B, and a ninth switch Q9 and a twelfth switch Q12 may be disposed for phase C.

The converter controller may control the switches Q1 to Q12 to be turned on or off ON/OFF by supplying PWM signals to gates of the switches Q1 to Q12. For example, the converter controller may supply a first PWM a-phase signal PWM1a to the gate of the first switch Q1 to control the on or off state of the first switch Q1. The converter controller may supply a second PWM a-phase signal PWM2a to the gate of the seventh switch Q7 to control the on or off state of the seventh switch Q7.

According to the on or off states of the respective switches Q1 to Q12, currents in the respective phases IA1, IB1, IC1, IA2, IB2, IC2 may be converted into direct currents and temporarily stored in DC-link capacitors Clink1, Clink2. For example, according to the on or off states of the first to sixth switches Q1 to Q6, each of the currents in the respective phases IA1, IB1, IC1 may be converted into a direct current and temporarily stored in the first DC-link capacitor Clink1. According to the on or off states of the seventh to twelfth switches Q7 to Q12, each of the currents in the respective phases IA2, IB2, IC2 may be converted into a direct current and temporarily stored in the second DC-link capacitor Clink2.

The switches Q1 to Q6 of the first PFC circuit 112 and the switches Q7 to Q12 of the second PFC circuit 114 may operate such that control values are consistent. Here, consistency may indicate that the control values are updated at the same interval.

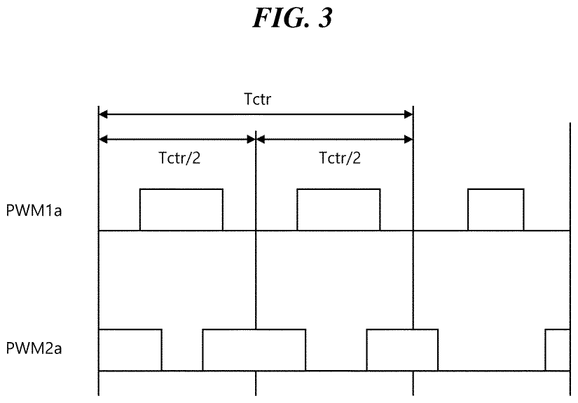

FIG. 3 is a waveform diagram of a first PWM a-phase signal and a second PWM a-phase signal according to an embodiment of the present disclosure.

Referring to FIG. 3, the first PWM a-phase signal PWM1a and the second PWM a-phase signal PWM2a may be changed during the same control period Tctr. For example, the duties of the first PWM a-phase signal PWM1a and the second PWM a-phase signal PWM2a may be changed during the same control period Tctr. In the example shown in FIG. 3, although the first PWM a-phase signal PWM1a and the second PWM a-phase signal PWM2 a have a phase difference of 180 degrees between each other, their control period Tctr may be substantially the same.

In the example shown in FIG. 3, one control period Tctr may include two switching periods Tctr/2, and both the first PWM a-phase signal PWM1a and the second PWM a-phase signal PWM2a may have the same switching period Tctr/2.

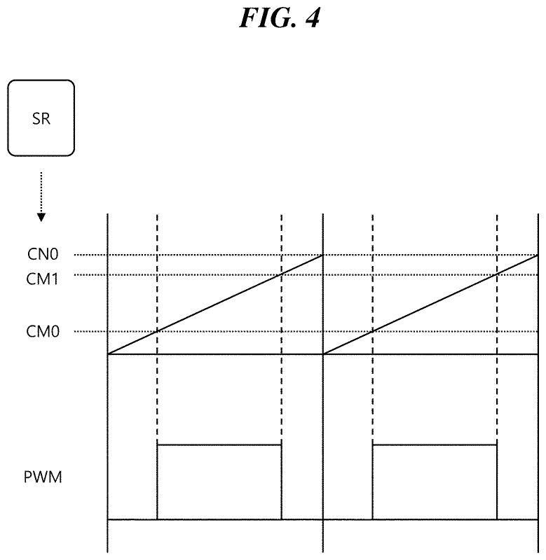

FIG. 4 is a schematic diagram showing elements that determine control values of each PWM signal according to an embodiment of the present disclosure.

Referring to FIG. 4, the control values of a PWM signal may include a duty and a period. The converter controller may control an output of each PFC circuit by performing PWM control over each switch. The PWM control may refer to control over the duty and the period of a PWM signal.

The converter controller may control the duty and the period of a PWM signal using a timer and registers.

For example, the converter controller may comprise a timer, and by comparing the value of the timer with the value of a first CN register CN0, the period of a PWM signal may be determined. The timer may operate by starting from an initial value (for example, 0), counting by increasing the value at predetermined intervals, and returning to the initial value when the value becomes equal to the value of the first CN register CN0. In this way, the period of a PWM signal may be determined by the value of the first CN register CN0.

For another example, the converter controller may set a rising edge of a PWM signal when the value of the timer becomes equal to the value of a first CM register CM0, and the converter controller may set a falling edge of the PWM signal when the value of the timer becomes equal to the value of a second CM register CM1. In this way, the duty of a PWM signal may be determined by the value of the first CM register CM0 and the value of the second CM register CM1.

The converter controller may calculate control values (for example, duty and period) for each PWM signal, and subsequently, may calculate register values corresponding to the control values. Then, the converter controller may update the registers with the calculated values to control each PWM signal.

In order to synchronize the update timing of the registers and to maintain consistent control, the converter controller may use a shadow register SR. The converter controller may calculate control values (for example, duty and period) for each PWM signal, and store them in the shadow register SR first. Then, the converter controller may set the transfer of the control values stored in the shadow register SR respectively to the registers CN0, CM0, CM1 at the beginning of the subsequent control period. In this way, the registers may be prevented from being arbitrarily updated and maintained in a consistent state.

The converter controller may comprise a core for calculation, which may execute a control algorithm to calculate control values for each PWM signal, calculate register values based on the control values, and then, update the shadow register.

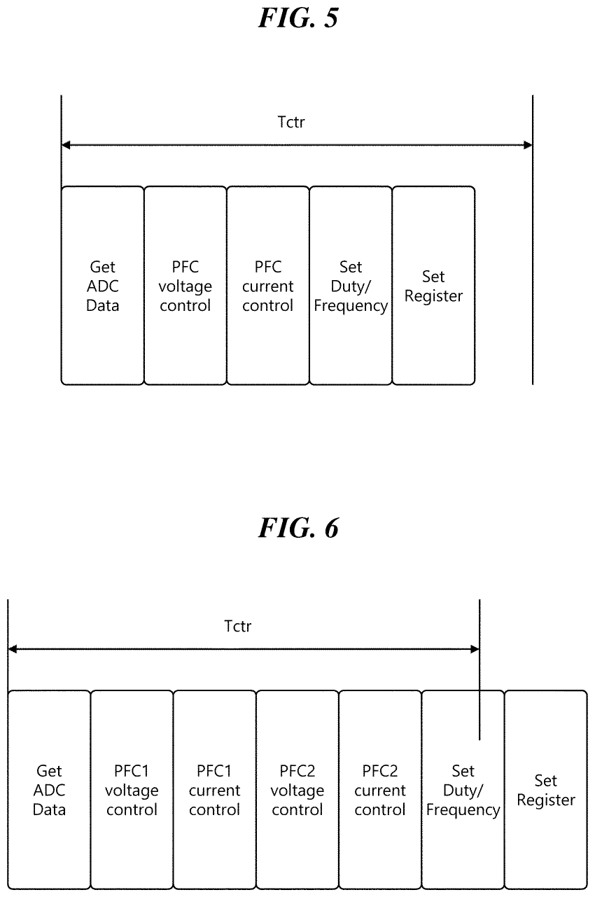

FIG. 5 is a schematic diagram showing a control process that one core performs in one control period.

Referring to FIG. 5, the core may perform a process of acquiring sensing values from an Analog-Digital Converter (ADC), a voltage control process, a current control process, a control value setting process, and a register setting process in each control period.

The converter controller may comprise multiple ADC channels. Each ADC channel may sense a current of each phase, a voltage of a DC-link capacitor, a voltage of an output node, and the like and convert them into digital values. The core may acquire sensing values from each ADC channel in an early time section of each control period.

The core may perform PFC voltage control based on an acquired ADC sensing value. For example, the core may compare a sensed voltage value of the DC-link capacitor with a reference voltage value, and may execute a control algorithm, designed to minimize a difference between the two values, in the voltage control process.

The core may perform PFC current control based on an ADC sensing value and resulting value of the PFC voltage control process. For example, the core may execute a control algorithm to maintain a current value of each phase at a predetermined level using the sensed current value of each phase and the resulting value of the PFC voltage control process in the PFC current control process.

The core may calculate control values (for example, duty and period) of a PWM signal for each switch based on a resulting value of the PFC current control process, and store calculated values in a predetermined data variable.

The core may read a value stored in the predetermined data variable, may calculate a register value based on the corresponding value, and may determine a register based on the calculated value.

FIG. 6 is a diagram illustrating problems that may occur when one core simultaneously controls two PFC circuits during one control period.

Referring to FIG. 6, one core may control two PFC circuits. In this case, since the core needs to separately calculate control values for the respective PFC circuits, it may need to perform each of the PFC voltage control process and the PFC current control process twice.

The core may perform a process of acquiring sensing values of an ADC, and subsequently, may first execute a voltage control process and a current control process for the first PFC circuit. Then, the core may perform a voltage control process and a current control process for the second PFC circuit. After calculating all control values for each PFC circuit in this manner, the core may perform a control value setting process and a register setting process.

However, there may be a possibility that one core cannot complete all of these processes within a single control period. In particular, when the core is optimized for controlling one PFC circuit, a problem may occur in which all processes cannot be performed within one control period when attempting to control two or more PFC circuits using the same core.

To address this problem, the converter controller according to an embodiment may use two cores to independently control respective PFC circuits.

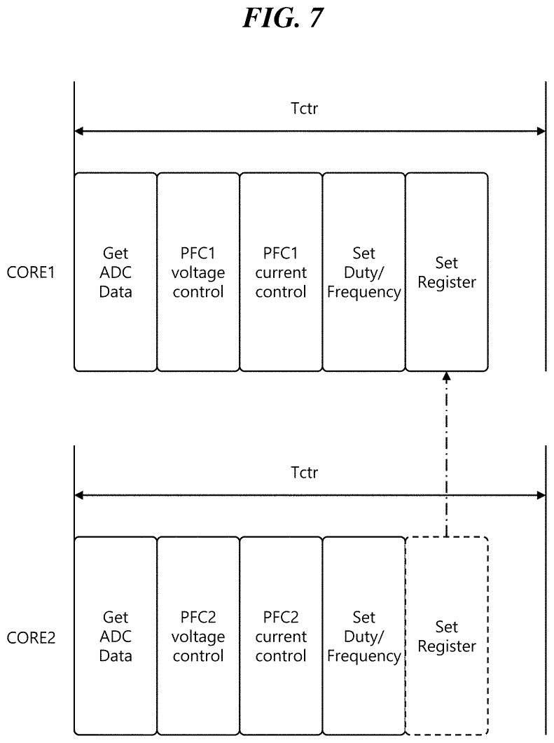

FIG. 7 is a diagram showing that two cores respectively control two PFC circuits in a converter controller according to an embodiment of the present disclosure.

Referring to FIG. 7, a first core may perform a process of acquiring a sensing value from an ADC connected to the first PFC circuit. The first core may then perform a voltage control process and a current control process for the first PFC circuit. In addition, the first core may perform a process of setting a control value required for the first PFC circuit and updating a register.

A second core may perform a process of acquiring a sensing value from an ADC connected to the second PFC circuit. Then, the second core may perform a voltage control process and a current control process for the second PFC circuit. Thereafter, the second core may perform a control value setting process required for the second PFC circuit.

In this case, when the second core independently performs a register setting process, a problem may occur. When the first core and the second core respectively perform register setting processes, one core may properly set a register while the other may fail to do so. For example, a case may occur where the first core completes the register setting normally, but the second core fails to complete it.

In such a case, the first PFC circuit and the second PFC circuit may be controlled without maintaining data consistency and may control values such as the switching period may not be synchronized, thereby causing a problem in which an excessive current flows through a particular circuit.

To resolve such a problem, a method may be applied in which one core (e.g., the first core) sets the registers of both PFC circuits. The first core may read the control values calculated by the second core, schematic calculate corresponding register values based on those control values, and then schematic set the registers of the second PFC circuit.

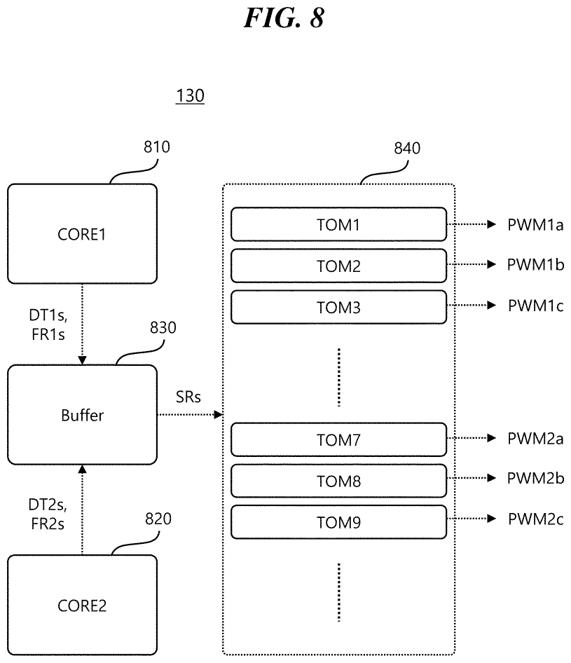

FIG. 8 is a schematic diagram of a converter controller according to an embodiment of the present disclosure.

Referring to FIG. 8, a converter controller 130 may comprise a first core 810, a second core 820, a buffer 830, and a timer module 840.

The converter controller 130 may be implemented in the form of a micro-controller unit (MCU).

An MCU is an integrated circuit for embedded systems that may include one or more processor cores. Such a core may have a configuration capable of processing 8-bit, 16-bit, 32-bit, or greater data. Depending on application requirements, it may be designed to include a plurality of 32-bit cores. Such a design may provide the capability to perform parallel processing and high-performance computation.

An MCU may comprise a hardware and software platform usable in automotive and industrial applications. An MCU may operate in environments requiring high-performance computation, communication, and data processing. Accordingly, it may be used to control various sensors and actuators and to execute complex control algorithms. By generating control signals or processing data, an MCU may contribute to improving system stability and efficiency.

An MCU may support functional safety at the ISO 26262 Automotive Safety Integrity Level-D (ASIL-D). This standard defines requirements to ensure safe operation in automotive applications. In accordance with these requirements, an MCU may include failure diagnosis, error detection, and recovery functions, thereby satisfying hardware and software design elements necessary to enhance the safety of automotive systems.

An MCU may comply with the AUTomotive Open System ARchitecture (AUTOSAR) 4.2 standard. This standard defines the software architecture of an electronic control unit (ECU), and an MCU may perform integrated functions within this architecture. Through compliance with the AUTOSAR, an MCU may provide a software platform that ensures interoperability among different suppliers and systems.

An MCU may include communication interfaces, data-processing capability, and security functions. An MCU may include, as the communication interfaces, a Controller Area Network (CAN), a Local Interconnect Network (LIN), FlexRay, or Ethernet, through which the MCU may exchange data with external devices. The data-processing capability may vary depending on the performance and the memory size of core(s) included in an MCU. In addition, an MCU may provide hardware security functions such as an encryption module or security authentication.

An MCU may collect and process sensor data and control actuators through various input and output interfaces. In this way, an MCU may support conversion between the physical world and digital signals. Further, an MCU may include functions of an Analog-to-Digital Converter (ADC), a Digital-to-Analog Converter (DAC), and Pulse Width Modulation (PWM), thereby enabling various control and conversion operations.

An MCU may include embedded memory and storage. Program code and data may be stored in embedded flash memory or Electrically Erasable Programmable Read-Only Memory (EEPROM). An MCU may also include a Random Access Memory (RAM) to process data required during execution. Such a memory configuration may be designed in various ways to meet application requirements.

Each of the first core 810 and the second core 820 may be one of a plurality of cores included in the MCU.

The first core 810 may, in each control period, acquire ADC sensing values and perform a voltage control process and a current control process for the first PFC circuit to calculate PWM control values for first switches included in the first PFC circuit (e.g., first duty values DT1s and first period values FR1s). The first core 810 may store control values DT1s, FR1s for the first switches in a data variable (e.g., a first new-data variable) included in the buffer 830.

The second core 820 may, in each control period, acquire ADC sensing values and perform a voltage control process and a current control process for the second PFC circuit to calculate PWM control values for second switches included in the second PFC circuit (e.g., second duty values DT2s and second period values FR2s). The second core 820 may store control values DT2s, FR2s for the second switches in a data variable (e.g., a second new-data variable) included in the buffer 830.

Here, the buffer 830 may be shared by the first core 810 and the second core 820. Accordingly, the first core 810 may access not only the first new-data variable but also the second new-data variable.

The first core 810 may check data variables (e.g., the first new-data variable and the second new-data variable) and, based on the values of those data variables, set registers for outputting PWM signals for the first switches and the second switches. In this case, the first core 810 may set values of shadow registers SRs included in the timer module 840.

The timer module 840 may take the form of a Generic Timer Module (GTM).

A GTM may be a hardware module capable of performing complex timing-and event-control tasks in embedded systems. The module may include various channels and may be used in applications requiring precise time-based control. A GTM may provide hardware-based timing management functions supporting tasks such as input-signal processing, output-signal generation, and timing control.

A GTM may be composed of sub-modules. Such sub-modules may include subordinate structures such as a Timer Output Module (TOM), an Advanced Timer Output Module (ATOM), a Timer Input Module (TIM), and a Time Base Unit (TBU). A TOM is a module that may support PWM (Pulse Width Modulation) signal generation and may be designed to allow independent control over each channel. An ATOM is a timing-control module that may provide higher precision and flexibility than a TOM. A TIM may process input signals to detect timing events or capture time data. A TBU may provide the time base that serves as a reference for timer operation.

A GTM may include an integrated clock-management mechanism. A Clock Management Unit (CMU) may provide appropriate clock signals to each sub-module of the GTM and may control timer frequency and accuracy. In this way, a GTM may support operation suitable for various timing requirements.

A GTM may support multi-channel operation. Accordingly, the timer module 840 may process multiple input and output signals concurrently, and each channel may be configured and controlled independently.

The timer module 840 may include a plurality of TOM channels (TOM1, TOM2, TOM3, . . . , TOM7, TOM8, TOM9, . . . ). Each of the TOM channels (TOM1, TOM2, TOM3, . . . , TOM7, TOM8, TOM9, . . . ) may output a respective PWM signal (PWM1a, PWM1b, PWM1c, . . . , PWM2a, PWM2b, PWM2c, . . . ) to control the on/off state of a corresponding one switch. For example, a first TOM channel TOM1 may output a first PWM a-phase signal PWM1a, a second TOM channel TOM2 may output a first PWM b-phase signal PWM1b, and a third TOM channel TOM3 may output a first PWM c-phase signal PWM1c. A seventh TOM channel TOM7 may output a second PWM a-phase signal PWM2a, an eighth TOM channel TOM8 may output a second PWM b-phase signal PWM2b, and a ninth TOM channel TOM9 may output a second PWM c-phase signal PWM2c.

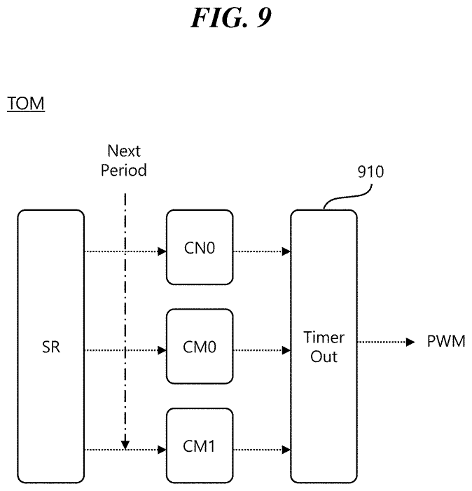

FIG. 9 is a schematic diagram of a TOM channel according to an embodiment of the present disclosure.

Referring to FIG. 9, a TOM channel may include registers such as a Shadow Register (SR), a first CN register (CN0: Compare Number Register 0), a first CM register (CM0: Compare Match Register 0), and a second CM register (CM1: Compare Match Register 1). The TOM channel may perform timer-based signal processing using these registers. Each register may perform a specific function in the process of generating or outputting a PWM signal.

The shadow register SR may be used as a space capable of temporarily storing values during operation. It may provide a configuration in which a new value can be applied stably while preventing a change in a register value from immediately affecting the timer output. This may enable a design that contributes to maintaining the continuity and stability of a signal during the PWM-signal generation process.

The first CN register CN0 may be configured as a register for storing or comparing a current value of a timer. It may be used to check a current state of the timer or to compare whether a timer value has reached a particular reference. The first CN register CN0 may store a value related to a timer period and may operate as a reference value required for generating a PWM-signal period.

The first CM register CM0 and the second CM register CM1 may be used to store reference values to be compared with a timer value. The first CM register CM0 may be used to switch a PWM signal to be in a high state or to trigger a particular operation when the timer value reaches a certain point. The second CM register CM1 may be used to switch a PWM signal to be in a low state or to perform another operation when the timer value reaches a certain point. Based on the values of these two registers, the duty cycle and the period of the PWM signal may be determined.

The TOM channel may include an output unit 910 that outputs a PWM signal according to the set values of the registers. The output unit 910 may process timer events based on register values and may generate a PWM signal to transfer it to an external system. The output unit 910 may be a hardware-designed block controlled by register values, and may operate in a manner that ensures accuracy and consistency of the PWM signal.

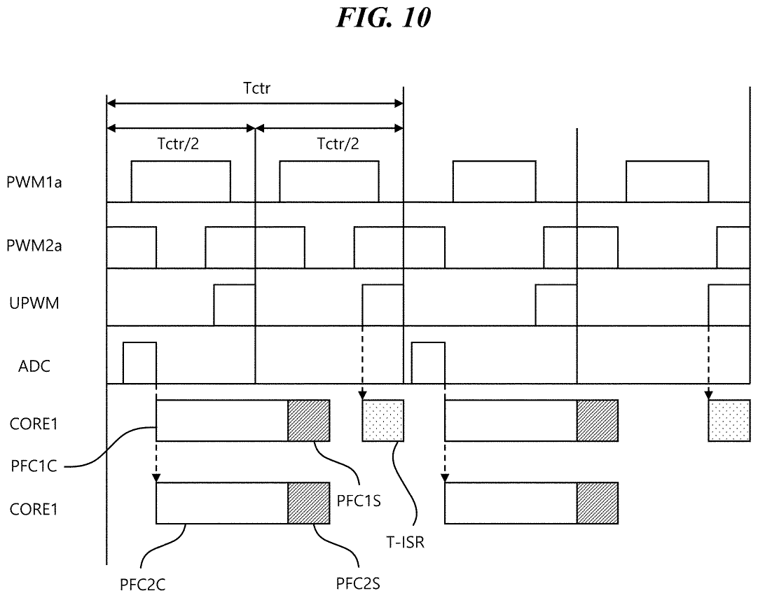

FIG. 10 is a diagram showing a process execution procedure of the cores and waveforms of main signals according to an embodiment of the present disclosure.

Referring to FIG. 10, in an early time section of each control period, the ADC may perform sensing. In response to an interrupt signal indicating completion of ADC sensing, the first core may perform a first control process PFC1C, and the second core may perform a second control process PFC2C.

In the first control process PFC1C, the first core may calculate PWM control values for the first switches included in the first PFC circuit. Within the first control process PFC1C, the first core may perform a process of acquiring ADC sensing values for the first PFC circuit, a voltage control process, and a current control process and then may calculate the PWM control values for the first switches. The first control process PFC1C may be performed in each control period.

In the second control process PFC2C, the second core may calculate PWM control values for the second switches included in the second PFC circuit. Within the second control process PFC2C, the second core may perform a process of acquiring ADC sensing values for the second PFC circuit, a voltage control process, and a current control process and then may calculate the PWM control values for the second switches. The second control process PFC2C may be performed in each control period.

After performing the first control process PFC1C, the first core may store the PWM control values calculated for the first switches in a first new-data variable PFC1S located in the buffer. After performing the second control process PFC2C, the second core may store the PWM control values calculated for the second switches in a second new-data variable PFC2S located in the buffer.

Then, the first core may, based on the values of the data variables stored in the buffer, set registers for outputting PWM signals for the first switches and set registers for outputting PWM signals for the second switches (T-ISR). Such a process may be performed in a top-level interrupt service routine (ISR) of the first core. In the top-level ISR, the first core may set registers for outputting PWM signals for the first switches and registers for outputting PWM signals for the second switches.

The top-level ISR may be invoked at a predetermined time before the start time of a new control period and may be terminated before the start time of the new control period. A UPWM may be generated in each switching period Tctr/2, and the next switching period may start at a falling edge of the UPWM. The top-level ISR may be invoked at a rising edge of the UPWM generated in a second switching period of one control period Tctr. From the invocation time of the top-level ISR until before the start time of the next control period, the first core may, based on the values of the data variables stored in the buffer, set registers for outputting PWM signals for the first switches and may set registers for outputting PWM signals for the second switches.

Meanwhile, if the PWM control values for the first switches and the PWM control values for the second switches are not stored in the first new-data variable and the second new-data variable, respectively, before the first core sets registers for outputting PWM signals for the first switches and registers for outputting PWM signals for the second switches, data consistency may not be ensured.

To ensure data consistency, the converter controller according to an embodiment may introduce pre-data variables that store control values of a previous control period and may introduce state variables that change values before and after the setting of the new-data variables.

In each control period, the first core may calculate PWM control values for the first switches included in the first PFC circuit (for example, the switches corresponding to Q1 through Q6 in FIG. 2) and may store them in the first new-data variable. In doing so, the first core may change a value of a first state variable before and after the storage and, after storage, may store the values of the first new-data variable in a first pre-data variable.

In each control period, the second core may calculate PWM control values for second switches included in the second PFC circuit (for example, the switches corresponding to Q7 through Q12 in FIG. 2) and may store them in the second new-data variable. In doing so, the second core may change a value of a second state variable before and after the storage and, after storage, may store the values of the second new-data variable in a second pre-data variable.

Then, according to the value of the first state variable, the first core may select one of the values of the first new-data variable and the first pre-data variable to set registers for outputting PWM signals for the first switches. Further, according to the value of the second state variable, the first core may select one of the values of the second new-data variable and the second pre-data variable to set registers for outputting PWM signals for the second switches.

For example, before storing the PWM control values in the first new-data variable, the first core may set the value of the first state variable to a first value (e.g., a value corresponding to a “WRITING” state) and, after storing the PWM control values of the first switches in the first new-data variable, may set the value of the first state variable to a second value (e.g., a value corresponding to a “COMPLETED” state). Likewise, before storing the PWM control values in the second new-data variable, the second core may set the value of the second state variable to the first value (e.g., a value corresponding to a “WRITING” state) and, after storing the PWM control values of the second switches in the second new-data variable, may set the value of the second state variable to the second value (e.g., a value corresponding to a “COMPLETED” state).

When the value of the first state variable is the second value, the first core may set registers for outputting PWM signals for the first switches according to the value of the first new-data variable. When the value of the second state variable is the second value, the first core may set registers for outputting PWM signals for the second switches according to the value of the second new-data variable.

When the value of the first state variable is the first value, the first core may set registers for outputting PWM signals for the first switches according to the value of the first pre-data variable. When the value of the second state variable is the first value, the first core may set registers for outputting PWM signals for the second switches according to the value of the second pre-data variable.

The first core may consider not only the value of the second state variable, whose state is changed by the other core, but also the value of the first state variable, whose state is changed by itself, because the process of setting the registers is performed in the top-level ISR. When the top-level ISR is invoked, other processes may be interrupted. If, at that time, the process of storing the PWM control values in the data variables is interrupted, the data variables may not be completely stored even in the first core. For this reason, the first core may also consider the value of the first state variable.

To ensure data consistency, the converter controller according to an embodiment may further consider the values of count variables.

Before storing the value of the first new-data variable in the first pre-data variable, the first core may increase the value of a first count variable. Before storing the value of the second new-data variable in the second pre-data variable, the second core may increase the value of a second count variable. When the value of the first count variable has not been increased, the first core may set registers for outputting PWM signals for the first switches according to the value of the first pre-data variable, and, when the value of the second count variable has not been increased, the first core may set registers for outputting PWM signals for the second switches according to the value of the second pre-data variable.

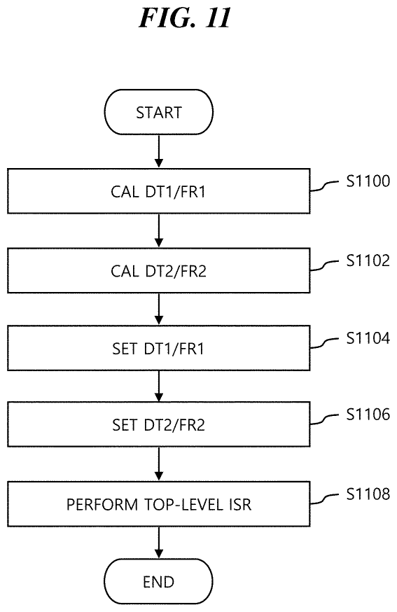

FIG. 11 is a flowchart illustrating a control method of a converter according to an embodiment of the present disclosure.

Referring to FIG. 11, the first core may calculate PWM control values for the first switches included in the first PFC circuit (S1100). The PWM control values may include at least one of a value indicating the duty of a PWM signal and a value indicating the period of the PWM signal.

The second core may calculate PWM control values for the second switches included in the second PFC circuit (S1102).

The first core may store the PWM control values of the first switches in the first new-data variable (S1104). In this case, the first core, which calculates the PWM control values of the first switches and stores them in the first new-data variable, may change the value of a first state variable before and after the storage and, after the storage, may store the value of the first new-data variable in the first pre-data variable. In one example, before storing the PWM control values of the first switches in the first new-data variable, the first core may set the value of the first state variable to the first value and, after storing the PWM control values of the first switches in the first new-data variable, may set the value of the first state variable to the second value.

The second core may store the PWM control values of the second switches in the second new-data variable (S1106). In this case, the second core, which calculates the PWM control values of the second switches and stores them in the second new-data variable, may change the value of a second state variable before and after the storage and, after the storage, may store the value of the second new-data variable in the second pre-data variable. In one example, before storing the PWM control values of the second switches in the second new-data variable, the second core may set the value of the second state variable to the first value and, after storing the PWM control values of the second switches in the second new-data variable, may set the value of the second state variable to the second value.

The first core may set registers for outputting PWM signals for the first switches according to the PWM control values of the first switches and may set registers for outputting PWM signals for the second switches according to the PWM control values of the second switches (S1108). This step may be performed in the top-level ISR of the first core. The top-level ISR may be invoked a at predetermined time before the start time of a new control period and may be terminated before the start time of the new control period.

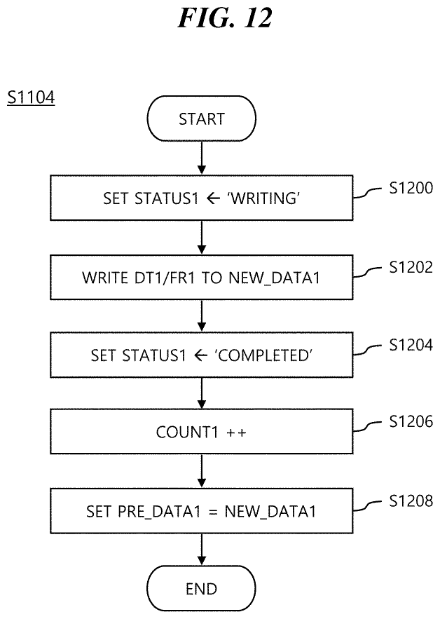

FIG. 12 is a detailed flowchart of step S1104 in the flowchart of FIG. 11.

Referring to FIG. 12, the first core may first set the value of the first state variable to the first value (e.g., a value corresponding to a “WRITING” state) (S1200). The value corresponding to the “WRITING” state may be, for example, 0 or 1.

After setting the value of the first state variable to the first value, the first core may store the PWM control values of the first switches in the first new-data variable (S1202). Here, the PWM control values may include at least one of a value indicating the duty of a PWM signal or a value indicating the period of the PWM signal.

After completion of the storage, the first core may set the value of the first state variable to the second value (e.g., a value corresponding to a “COMPLETED” state) (S1204). The value corresponding to the “COMPLETED” state may be, for example, 1 or 0.

The first core may then increase the value of the first count variable (S1206).

The first core may then store the value of the first new-data variable in the first pre-data variable (S1208). The first new-data variable, the first pre-data variable, and the first state variable may be located in a buffer shared by the first core and the second core.

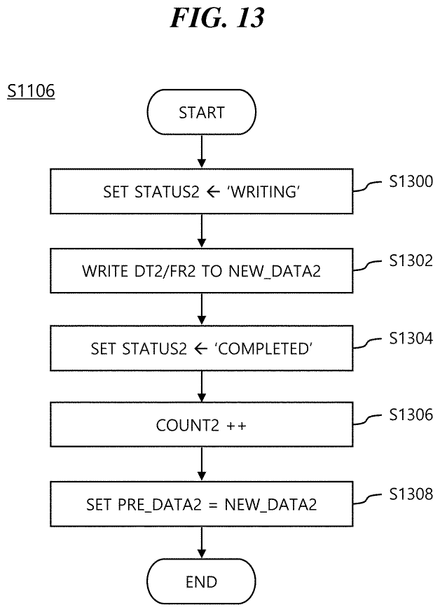

FIG. 13 is a detailed flowchart of step S1106 in the flowchart of FIG. 11.

Referring to FIG. 13, the second core may first set the value of the second state variable to the first value (e.g., a value corresponding to a “WRITING” state) (S1300). The value corresponding to the “WRITING” state may be, for example, 0 or 1.

After setting the value of the second state variable to the first value, the second core may store the PWM control values of the second switches in the second new-data variable (S1302). Here, the PWM control values may include at least one of a value indicating the duty of a PWM signal and a value indicating the period of the PWM signal.

After completion of the storage, the second core may set the value of the second state variable to the second value (e.g., a value corresponding to a “COMPLETED” state) (S1304). The value corresponding to the “COMPLETED” state may be, for example, 1 or 0.

The second core may then increase the value of the second count variable (S1306).

The second core may then store the value of the second new-data variable in the second pre-data variable (S1308). The second new-data variable, the second pre-data variable, and the second state variable may be located in a buffer shared by the first core and the second core.

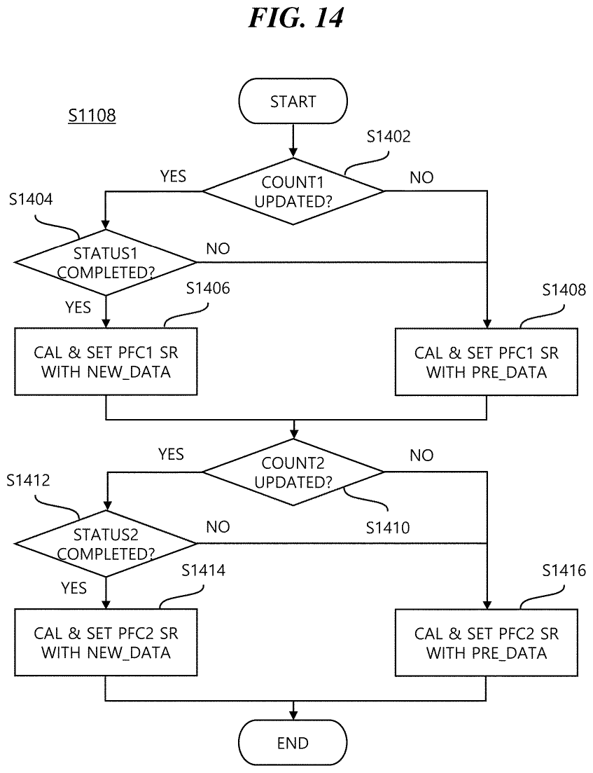

FIG. 14 is a detailed flowchart of step S1108 in the flowchart of FIG. 11.

Referring to FIG. 14, the first core may check whether the first count variable has been updated (e.g., increased) compared with the previous control period (S1402).

If the first count variable has not been updated (NO in S1402), the first core may set registers for outputting PWM signals for the first switches according to the value of the first pre-data variable (S1408).

The step of setting the registers (e.g., S1408) may include a step of calculating values for the registers and a step of setting the registers to those values.

In one example, the first core may calculate a first CN register value to correspond to a value indicating the period of the PWM signal included in the PWM control values. The first core may store the first CN register value in one shadow register corresponding to the first CN register. The value stored in this shadow register may be transferred to the first CN register simultaneously with the start of the next control period.

In another example, the first core may calculate a first CM register value and a second CM register value to correspond to a value indicating the duty of the PWM signal included in the PWM control values. The first CM register value may be a value used for setting a rising edge of the PWM signal (e.g., a rising-edge time value) and the second CM register value may be a value used for setting a falling edge of the PWM signal (e.g., a falling-edge time value). The first core may store the first CM register value in another shadow register corresponding to the first CM register and may store the second CM register value in yet another shadow register corresponding to the second CM register. The value stored in the other shadow register and the value stored in the yet other shadow register may be transferred to the first CM register and the second CM register, respectively, simultaneously with the start of the next control period.

In the step of setting the registers (e.g., S1408), the first core may substantially set the shadow registers corresponding respectively to the TOMs.

If, in step S1402, the first count variable has been updated (YES in S1402), the first core may check the first state variable (S1404). If the first state variable is not the second value (e.g., a value corresponding to a “COMPLETED” state (NO in S1404)), the first core may perform step S1408.

If the first state variable is the second value (e.g., a value corresponding to a “COMPLETED” state (YES in S1404)), the first core may set registers for outputting PWM signals for the first switches according to the value of the first new-data variable (S1406).

The first core may then check whether the second count variable has been updated (e.g., increased) compared with the previous control period (S1410).

If the second count variable has not been updated (NO in S1410), the first core may set registers for outputting PWM signals for the second switches according to the value of the second pre-data variable (S1416).

If, in step S1410, the second count variable has been updated (YES in S1410), the first core may check the second state variable (S1412). If the second state variable is not the second value (e.g., a value corresponding to a “COMPLETED” state (NO in S1412)), the first core may perform step S1416.

If the second state variable is the second value (e.g., a value corresponding to a “COMPLETED” state (YES in S1412)), the first core may set registers for outputting PWM signals for the second switches according to the value of the second new-data variable (S1414).

As described above, according to the present embodiment, a plurality of PFC circuits may be controlled in a synchronized manner. Further, when a plurality of PFC circuits is controlled by different cores, data consistency may be ensured.

As used herein, terms, such as “include,” “comprise,” or “have,” are intended to indicate the possibility that the corresponding component is present, unless expressly stated otherwise. The terms are not intended to exclude other components and should be interpreted to allow the inclusion of other components. All terms, including technical or scientific terms, unless otherwise defined, have the same meanings as commonly understood by those of ordinary skill in the art to which the present invention pertains. Terms generally used, such as those defined in dictionaries, should be interpreted consistently with the contextual meaning in the relevant art and, unless clearly defined in the present specification and should not be interpreted in an idealized or excessively formal sense.

The foregoing description is merely illustrative of the technical spirit of the present invention. Various modifications and variations can be made by those of ordinary skill in the art without departing from the essential characteristics of the present invention. Therefore, the embodiments disclosed herein are not intended to limit but to describe the technical spirit of the present invention, and the scope of the invention is not limited by these embodiments. The protection scope of the present disclosure should be interpreted according to the following claims, and all technical ideas within the equivalent scope thereof should be interpreted as being included within the protection scope of the present disclosure.

What is claimed is:

1. A converter controller, comprising:
a first core configured to:
calculate pulse width modulation (PWM) control values for first switches included in a first power factor correction (PFC) circuit; and
store the PWM control values in a first new-data variable in each control period, wherein a value of a first state variable is changed before and after storing the PWM control values in the first new-data variable in each control period, and a value of the first new-data variable is stored in a first pre-data variable after storing the PWM control values in the first new-data variable in each control period; and
a second core configured to:
calculate PWM control values for second switches included in a second PFC circuit;
set registers for outputting PWM signals for the second switches in the same control period;
select one of the values of the first new-data variable and the first pre-data variable; and
set registers for outputting PWM signals for the first switches.

2. The converter controller of claim 1, wherein the first core is further configured to:
set the first state variable to a first value before storing the PWM control values for the first switches in the first new-data variable; and
set the first state variable to a second value after storing the PWM control values for the first switches in the first new-data variable.

3. The converter controller of claim 2, wherein the second core is further configured to:
set the registers for outputting PWM signals for the first switches based on the first new-data variable when the first state variable includes the second value; and
set the registers for outputting PWM signals for the first switches based on the first pre-data variable when the first state variable includes the first value.

4. The converter controller of claim 1, wherein the second core is further configured to:
calculate the PWM control values for the second switches; and
store the PWM control values for the second switches in a second new-data variable,
wherein a value of a second state variable is stored before and after storing the PWM control values for the second switches in the second new-data variable, and
wherein a value of the second new-data variable is stored in a second pre-data variable after storing the PWM control values for the second switches in the second new-data variable.

5. The converter controller of claim 4, wherein the second core is further configured to set registers for outputting PWM signals for the second switches by selecting one of the values of the second new-data variable and the second pre-data variable based on the value of the second state variable.

6. The converter controller of claim 5, wherein the second core is further configured, in a top-level Interrupt Service Routine (ISR), to set registers for outputting PWM signals for the first switches and registers for outputting PWM signals for the second switches.

7. The converter controller of claim 6, wherein the top-level ISR is invoked at a predetermined time before a start time of a new control period and is terminated before the start time of the new control period.

8. The converter controller of claim 1, wherein the PWM control values include at least one of a value indicating a duty of a PWM signal or a value indicating a period of the PWM signal.

9. The converter controller of claim 1, wherein the second core is further configured to:
generate a rising-edge time value or a falling-edge time value of a PWM signal from one of a value of the first new-data variable and a value of the first pre-data variable; and
store the rising-edge time value or the falling-edge time value in the registers for outputting PWM signals for the first switches.

10. The converter controller of claim 1, further comprising Timer Output Modules (TOMs) configured to output PWM signals respectively to the first switches and the second switches,
wherein the second core is further configured to set shadow registers (SRs) corresponding to the respective TOMs.

11. The converter controller of claim 10, wherein each TOM includes a first CM register used for setting a rising edge of a PWM signal and a second CM register used for setting a falling edge of the PWM signal, and
wherein values stored in a shadow register is transferred, at a start of a control period, to the first CM register and the second CM register.

12. The converter controller of claim 1, wherein:
in each control period, the first core is further configured to calculate PWM control values for the first switches after acquiring Analog-Digital-Converter (ADC) sensing values, performing a voltage control process, and performing a current control process for the first PFC circuit, and
in each control period, the second core is further configured to calculate PWM control values for the second switches after acquiring ADC sensing values, performing a voltage control process, and performing a current control process for the second PFC circuit.

13. The converter controller of claim 1, wherein the first core is further configured to increase a value of a count variable before storing the value of the first new-data variable in the first pre-data variable, and
when the value of the count variable has not been increased, the second core is further configured to set registers for outputting PWM signals for the first switches according to a value of the first pre-data variable.

14. The converter controller of claim 1, wherein the first new-data variable and the first pre-data variable are located in a buffer shared by the first core and the second core.

15. A converter control method, comprising:
calculating, by a first core, Pulse Width Modulation (PWM) control values for first switches included in a first Power Factor Correction (PFC) circuit;
calculating, by a second core, PWM control values for second switches included in a second PFC circuit;
storing, by the first core, the PWM control values of the first switches in a first new-data variable;
storing, by the second core, the PWM control values of the second switches in a second new-data variable, wherein a value of a first state variable is changed before and after storing the PWM control values of the second switches in the second new-data variable, and a value of the second new-data variable is stored in a second pre-data variable after storing the PWM control values of the second switches in the second new-data variable;
setting, by the first core, registers for outputting PWM signals for the first switches based on the PWM control values of the first switches; and
selecting, by the first core based on the value of the first state variable, one of values of the second new-data variable and the second pre-data variable to set registers for outputting PWM signals for the second switches.

16. The converter control method of claim 15, wherein storing the PWM control values of the second switches in the second new-data variable includes:
setting, by the second core, the value of the first state variable to a first value before storing the PWM control values of the second switches in the second new-data variable; and
setting, by the second core, the value of the first state variable to a second value after storing the PWM control values of the second switches in the second new-data variable.

17. The converter control method of claim 16, wherein, setting the registers for outputting PWM signals for the second switches includes:
setting, by the first core, registers for outputting PWM signals for the second switches based on a value of the second new-data variable when the value of the first state variable is the second value; and
setting, by the first core, registers for outputting PWM signals for the second switches based on a value of the second pre-data variable when the value of the first state variable is the first value.

18. The converter control method of claim 15, wherein:
storing the PWM control values of the first switches in the first new-data variable includes:
calculating, by the first core, the PWM control values of the first switches; and
storing, by the first core, the PWM control values of the first switches in the first new-data variable, wherein a value of a second state variable is changed before and after storing the PWM control values of the first switches in the first new-data variable, and a value of the first new-data variable is stored in a first pre-data variable after storing the PWM control values of the first switches in the first new-data variable; and
setting the registers for outputting PWM signals for the first switches includes:
setting, by the first core, registers for outputting PWM signals for the first switches based on a value of the first new-data variable when the value of the second state variable is a second value; and
setting, by the first core, registers for outputting PWM signals for the first switches based on a value of the first pre-data variable when the value of the second state variable is a first value.

19. The converter control method of claim 18, wherein setting the registers for outputting PWM signals for the first switches is performed in a top-level Interrupt Service Routine (ISR) of the first core.

20. The converter control method of claim 19, wherein the top-level ISR is invoked at a predetermined time before a start time of a new control period and is terminated before the start time of the new control period.
